(19) United States
(12) Patent Application Publication
(10) Pub. No.: US 2018/0182653 A1
(43) Pub. Date: Jun. 28, 2018

(54) ELECTRONIC SYSTEM FOR TESTING AND CONTROLLING SEMICONDUCTOR MANUFACTURING EQUIPMENT

(71) Applicant: SAMSUNG ELECTRONICS CO., LTD., Suwon-si (KR)

(72) Inventors: HyunJin CHONG, Pyeongtaek-si (KR); Myoungseok LEE, Yongin-si (KR); YuneTech HAN, Hwaseong-si (KR)

(21) Appl. No.: 15/654,163

(22) Filed: Jul. 19, 2017

(30) Foreign Application Priority Data
Dec. 27, 2016 (KR) 10-2016-0180316

(51) Int. Cl. H01L 21/67; G06F 11/36; G06F 11/263; H01L 21/677; H01L 21/66

(52) U.S. Cl. CPC H01L 21/67242; G06F 11/3684; H01L 22/20; H01L 21/67011; H01L 21/67745; G06F 11/263

(57) ABSTRACT

An electronic system includes a memory and a processor. The memory stores first setting data of a manufacturing process condition of semiconductor manufacturing equipment. The processor judges whether a change has occurred in the semiconductor manufacturing equipment based on first equipment data from the semiconductor manufacturing equipment and second equipment data stored in the memory before the first equipment data is received. The processor transmits second setting data to the semiconductor manufacturing equipment when the change has occurred in the semiconductor manufacturing equipment and stores the first equipment data in the memory when no change has occurred in the semiconductor manufacturing equipment. The second setting data corresponds to updated first setting data.

### CROSS-REFERENCE TO RELATED APPLICATION

Korean Patent Application No. 10-2016-0180316, filed on Dec. 27, 2016, and entitled, “Electronic System for Testing and Controlling Semiconductor Manufacturing Equipment,” is incorporated by reference herein in its entirety.

### BACKGROUND

### 1. Field

One or more embodiments described herein relate to an electronic system for testing and controlling semiconductor manufacturing equipment.

### 2. Description of the Related Art

A variety of processes are used to manufacture a semiconductor device. Many of these processes use different equipment. Examples include a wafer cleaning device, a wafer etching device, a doping device, a photographic equipment device, a chemical and mechanical polishing device, a semiconductor packing device, and a test device.

This equipment has a finite useful life. For example, conditions may change which make the equipment obsolete or the equipment may break down over time or require replacement. It often takes engineers substantial time to determine what changes are needed and/or which equipment needs repair or replacement. Moreover, when semiconductor manufacturing equipment is initially installed or assembled, the equipment may not be assembled as designed or may be installed in an improper manner.

### SUMMARY

In accordance with one or more embodiments, an electronic system includes a memory to store first setting data of a manufacturing process condition of a semiconductor manufacturing equipment; and a processor to judge whether a change has occurred in the semiconductor manufacturing equipment based on first equipment data from the semiconductor manufacturing equipment and second equipment data stored in the memory before the first equipment data is received, wherein: the processor transmits second setting data to the semiconductor manufacturing equipment when the change has occurred in the semiconductor manufacturing equipment and stores the first equipment data in the memory when no change has occurred in the semiconductor manufacturing equipment, the second setting data relating to updated first setting data.

In accordance with one or more other embodiments, an electronic system includes a memory to store first setting data corresponding to a manufacturing process condition of a first semiconductor manufacturing equipment and second setting data corresponding to a manufacturing process condition of a second semiconductor manufacturing equipment; and a processor to judge a cause of a change in the first semiconductor manufacturing equipment and transmit the second setting data to the first semiconductor manufacturing equipment based on a judgment result when first equipment data from the first semiconductor manufacturing equipment includes first error information corresponding to the first semiconductor manufacturing equipment and second equipment data from the second semiconductor manufacturing equipment does not include second error information corresponding to the second semiconductor manufacturing equipment.

In accordance with one or more other embodiments, a system includes first logic to detect a change in equipment; second logic to generate control information of the equipment; and third logic to transmit the generated control information to the equipment, wherein the first logic is to detect the change in the equipment based on a first equipment data from the equipment and second equipment data stored in the memory and wherein the equipment includes semiconductor manufacturing equipment.

### BRIEF DESCRIPTION OF THE DRAWINGS

Features will become apparent to those of skill in the art by describing in detail exemplary embodiments with reference to the attached drawings in which:

FIG. 1 illustrates an embodiment of a semiconductor manufacturing and management system;

FIG. 2 illustrates an embodiment of an electronic system;

FIG. 3 illustrates an embodiment of a method for updating equipment data of the electronic system;

FIG. 4 illustrates an embodiment of a method for storing equipment data of the electronic system;

FIG. 5 illustrates an embodiment of a method for updating recipe data of the electronic system;

FIG. 6 illustrates an embodiment of a method for generating control information of the electronic system;

FIG. 7 illustrates another embodiment of a method for generating control information of the electronic system;

FIG. 8 illustrates another embodiment of a semiconductor manufacturing and management system;

FIG. 9 illustrates an embodiment of a method for setting semiconductor manufacturing equipment of the system in FIG. 8;

FIG. 10 illustrates an embodiment of a method for storing equipment data of the system in FIG. 8;

FIG. 11 illustrates an embodiment of a method for updating data of first semiconductor manufacturing equipment of the system in FIG. 8; and

FIG. 12 illustrates another method for updating data of first semiconductor manufacturing equipment of the system in FIG. 8.

### DETAILED DESCRIPTION

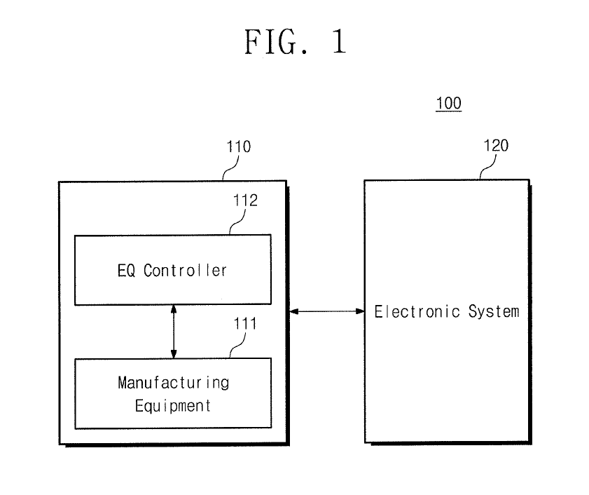

FIG. 1 illustrates an embodiment of a semiconductor manufacturing and management system 100 which may include a semiconductor manufacturing system 110 and an electronic system 120. The semiconductor manufacturing system 110 may include semiconductor manufacturing equipment 111 and a manufacturing equipment controller 112. The semiconductor manufacturing equipment 111 may be a device for a manufacturing process of a semiconductor device. The semiconductor manufacturing equipment 111 may include at least one of a wafer cleaning device, a wafer etching device, a doping device, a photographic equipment device, a chemical and mechanical polishing (CMP) device, a semiconductor packing device, a test device, or another type of equipment.

The semiconductor manufacturing equipment 111 may follow a standard protocol of data communication to interface with other devices (e.g., manufacturing equipment controller 112 and electronic system 120). The semiconductor manufacturing equipment 111 may use, for example, a SEMI equipment communication standard SECS protocol. In one embodiment, the semiconductor manufacturing equipment 111 may be a Non-SECS device that does not use the SECS protocol. When the semiconductor manufacturing equipment 111 is a Non-SECS device, the semiconductor manufacturing equipment 111 may use, for example, a high-speed SECS message service HSMS protocol obtained by improving the SECS protocol.

The semiconductor manufacturing equipment 111 may transmit equipment data generated in a manufacturing process of a semiconductor device to the manufacturing equipment controller 112 according to the standard protocol. The equipment data may include information (e.g., a temperature value, a pressure value, time for a manufacturing process) measured in or by semiconductor manufacturing equipment 111.

The manufacturing equipment controller 112 may receive and analyze equipment data from the semiconductor manufacturing equipment 111 and monitor an operational status of semiconductor manufacturing equipment 111. The manufacturing equipment controller 112 may include equipment setting data, which may include information indicative of manufacturing process conditions set in the semiconductor device. The equipment setting data may include, for example, data indicative of a manufacturing process order of the semiconductor manufacturing equipment 111, data indicative of the performance environment of a manufacturing process, and recipe data including conditions for a manufacturing process. The recipe data may include, for example, temperature information, pressure information, process time information, and/or other information set in the semiconductor manufacturing equipment 111.

When components of the semiconductor manufacturing equipment 111 are exchanged or replaced, the semiconductor manufacturing equipment 111 may be cleaned. Or, when a manufacturing process method of the semiconductor manufacturing equipment 111 is changed, equipment setting data stored in the manufacturing equipment controller 112 may be updated. For example, as the semiconductor manufacturing equipment 111 ages, equipment setting data stored in the manufacturing equipment controller 112 may be updated. This may be performed manually. For example, the equipment setting data stored in the manufacturing equipment controller 112 may be updated by an engineer. The engineer searches equipment setting data to be updated of the semiconductor manufacturing equipment 111 and updates the searched setting data. This manual process takes a lot of time and thus is inefficient.

In accordance with the present embodiment, the manufacturing equipment controller 112 may include hardware, software, or a hybrid of both to perform various operations. For example, the manufacturing equipment controller 112 may include a special-purpose hardware circuit to perform a specific operation. The manufacturing equipment controller 112 may include one or more processor cores for executing instruction sets of program code for performing specific operations.

The electronic system 120 may be or include, for example, a desktop computer, a laptop computer, a workstation, or a server system. The electronic system 120 may be, for example, a working information electronic system that provides information that is indicative of situation information of the semiconductor manufacturing equipment 111. The electronic system 120 may receive equipment data generated in a manufacturing process of the semiconductor manufacturing equipment 111 from the semiconductor manufacturing system 110. The electronic system 120 may receive equipment data from the semiconductor manufacturing equipment 111 or the manufacturing equipment controller 112.

The electronic system 120 may analyze the received equipment data and judge whether there are changes in the semiconductor manufacturing equipment 111. When there are changes in the semiconductor manufacturing equipment 111, the electronic system 120 may update data including the cause of error among equipment setting data stored in the manufacturing equipment controller 112 to new data. When there are changes in the semiconductor manufacturing equipment 111, the electronic system 120 may provide information indicating the cause of component change, changed components, and recommended corresponding methods to an engineer. Changes in the components may occur, for example, due to various causes such as defects in components, failures of components, or deteriorations of components. Change in equipment may correspond to an fault occurrence in the semiconductor manufacturing equipment.

The electronic system 120 may receive equipment data including information, indicating changes in the semiconductor manufacturing equipment 111, from the semiconductor manufacturing system 110. When the equipment data includes error information of the equipment setting data, the electronic system 120 may update data, including the cause of error among equipment setting data stored in the manufacturing equipment controller 112, to new data. When the equipment data includes information about changes in components of the semiconductor manufacturing equipment 111, the electronic system 120 may provide information indicating the cause of component change, changed components, and recommended corresponding methods to an engineer. The electronic system 120 may provide working information that reflects current situation information of the semiconductor manufacturing equipment 111 to an engineer. The electronic system 120 may analyze the received equipment data to judge whether there are changes in the semiconductor manufacturing equipment 111.

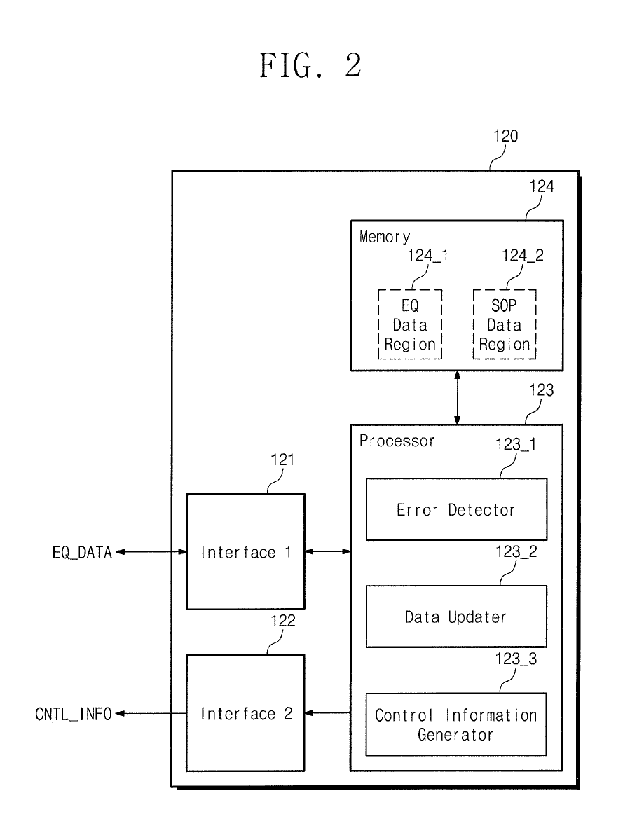

FIG. 2 illustrates an embodiment of the electronic system 120 in FIG. 1. Referring to FIG. 2, the electronic system 120 may include a first interface 121, a second interface 122, a processor 123, and a memory 124. The electronic system 120 may communicate with the semiconductor manufacturing system 110 in FIG. 1 through the first interface 121. The first interface 121 may receive equipment data EQ_DATA from the semiconductor manufacturing system 110. For example, after a reference time has elapsed from when the equipment data EQ_DATA is received, next equipment data may be received. The first interface 121 may transmit the received equipment data EQ_DATA to the processor 123.

The electronic system 120 may transmit control information CNTL_INFO to an external device through the second interface 122. The control information CNTL_INFO may be generated in the processor 123 based on the equipment data EQ_DATA from the semiconductor manufacturing system 110. The control information CNTL_INFO may include information indicating the cause of a change of the semiconductor manufacturing equipment 111, information indicating changed components, and recommended corresponding methods, and/or other information. The control information CNTL_INFO may be working information to be provided to an engineer. The external device may be a portable electronic device of an engineer. The external device may include at least one of a mobile phone, a smart phone, a wearable device, a notebook computer, or a personal digital assistant (PDA).

The first and second interfaces 121 and 122 may transmit and receive data through a wired or wireless communication. The first and second interfaces 121 and 122 may use, for example, an Ethernet communication method using TCP (transmission control protocol) or IP (internet protocol) or another type of wired or wireless communication method.

The processor 123 may include an error detector 123_1, a data updater 123_2, and a control information generator 123_3. Each of the error detector 123_1, the data updater 123_2, and the control information generator 123_3 may include a hardware configuration, a software configuration, and/or a hybrid of both to perform various operations. Each of the error detector 123_1, the data updater 123_2, and the control information generator 123_3 may be implemented, for example, by one or more processor cores.

Each of the error detector 123_1, the data updater 123_2, and the control information generator 123_3 may include a special-purpose hardware circuit to perform a specific operation. Each of the error detector 123_1, the data updater 123_2, and the control information generator 123_3 may be implemented by an instruction set of a program code for performing a specific operation.

The error detector 123_1 may analyze the equipment data EQ_DATA from the semiconductor manufacturing system 110. The error detector 123_1 may analyze the equipment data EQ_DATA to cache the flow of a manufacturing process of the semiconductor manufacturing equipment 111. For example, the error detector 123_1 may judge whether changes occur in the semiconductor manufacturing equipment 111 based on an analysis of the equipment data EQ_DATA. The error detector 123_1 may determine information indicating whether equipment setting data of the semiconductor manufacturing equipment 111 is changed or indicating changes of components of the semiconductor manufacturing equipment 111.

When the equipment setting data of the semiconductor manufacturing equipment 111 is changed, the error detector 123_1 may transmit the equipment setting data to the data updater 123_2. The error detector 123_1 may receive the equipment setting data from the memory 124. The equipment setting data may be received from the semiconductor manufacturing system 110 through the first interface 121. The equipment setting data may be stored in the memory 124 in advance.

When it is judged that a change has occurred in components of the semiconductor manufacturing equipment 111, the error detector 123_1 may transmit information indicating the changes of components to the control information generator 123_3. The error detector 123_1 may receive the component information from the memory 124. When it is judged that there are no changes in components of the semiconductor manufacturing equipment 111, the error detector 123_1 may store the equipment data EQ_DATA in the memory 124.

The data updater 123_2 may update the equipment setting data of the semiconductor manufacturing equipment 111. The data updater 123_2 may update data indicating the cause of error among the equipment setting data to new equipment setting data. The new equipment setting data may be set to a value that is optimized for a manufacturing process environment of the semiconductor manufacturing equipment 111. The new equipment setting data may be transmitted to at least one of the semiconductor manufacturing equipment 111 or the manufacturing equipment controller 112.

The control information generator 123_3 may generate control information CNTL_INFO. When information indicating changes in components is received from the error detector 123_1 to the control information generator 123_3, the control information generator 123_3 may generate control information CNTL_INFO based on the information indicating changes in components and standard operating procedure data SOP_DATA from the memory 124. The standard operating procedure data SOP_DATA may include all or a variety of information corresponding to the semiconductor manufacturing equipment 111, such as but not limited to component information (e.g., the type of component, component specification, etc.), an installation method, and a management method of the semiconductor manufacturing equipment 111.

The memory 124 may include a manufacturing equipment data area 124_1 and a standard operating procedure data area 124_2. The memory 124 may store equipment setting data of the semiconductor manufacturing equipment 111. The memory 124 may store the equipment data EQ_DATA from the processor 123 in the manufacturing equipment data area 124_1. The equipment data EQ_DATA may be updated at regular time intervals. The memory 124 may store standard operating procedure data SOP_DATA with respect to the semiconductor manufacturing equipment 111 in the standard operating procedure data area 124_2. The memory 124 may manage data using a database scheme.

The memory 124 may include at least one of various nonvolatile memories such as a phase-change random access memory PRAM, a magneto-resistive RAM MRAM, a resistive RAM ReRAM, a ferro-electric RAM FRAM, etc. In some embodiments, the memory 124 may include a volatile memory such as a static RAM SRAM, a dynamic RAM DRAM, a synchronous DRAM SDRAM, etc.

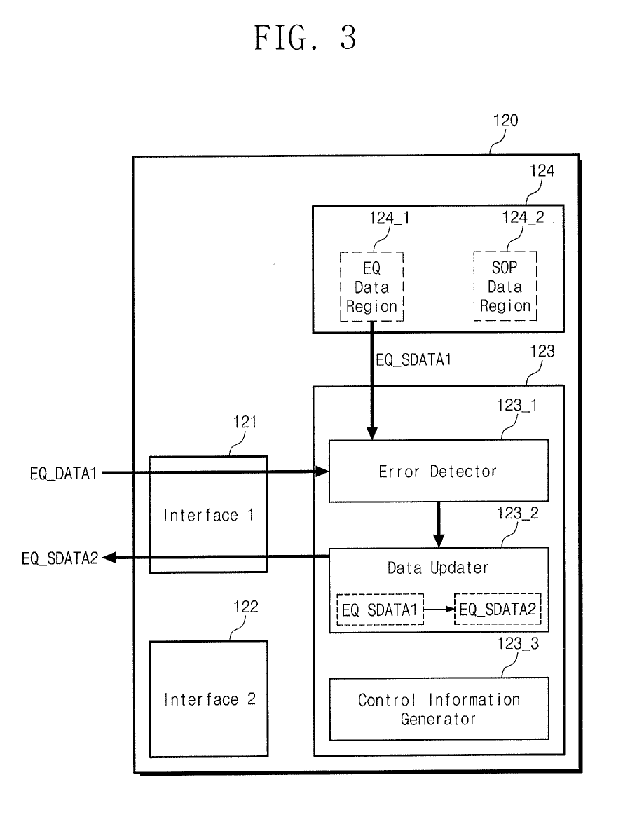

FIG. 3 illustrates an embodiment of a method for updating equipment data of the electronic system 120 in FIG. 2. Referring to FIG. 3, the error detector 123_1 may receive first equipment data EQ_DATA1 through the first interface 121. The first equipment data EQ_DATA1 may include various type of data associated with the manufacturing process(es) of the semiconductor manufacturing equipment 111.

The error detector 123_1 may analyze the first equipment data EQ_DATA1. In one embodiment, the error detector 123_1 may be provided with equipment data received before the first equipment data EQ_DATA1 from the memory 124. The error detector 123_1 may judge whether any changes have occurred in the semiconductor manufacturing equipment 111, for example, by comparing the equipment data received before the first equipment data EQ_DATA1 with the first equipment data EQ_DATA1.

For example, when a temperature value and a pressure value in the first equipment data EQ_DATA1 increase by more than a reference value as compared with a temperature value and a pressure value of the equipment data received before the first equipment data EQ_DATA1, the error detector 123_1 may judge that changes in the semiconductor manufacturing equipment 111 have occurred. When it is judged that there are changes in the semiconductor manufacturing equipment 111, the error detector 123_1 may analyze a cause of the changes.

According to one example, changes may be determined to have occurred in a mass flow controller MFC of the semiconductor manufacturing equipment 111. The error detector 123_1 may identify and/or interpret data or components associated with errors in the first equipment data EQ_DATA1. This is merely an example and changes may occur in various components, e.g., a radio frequency source, a bias power, a valve, and a thermometer of the semiconductor manufacturing equipment 111.

When changes occur in the semiconductor manufacturing equipment 111, the processor 123 may update first setting equipment data EQ_SDATA1. The first setting equipment data EQ_SDATA1 may be or include recipe data associated with a manufacturing process of the semiconductor manufacturing equipment 111. For example, the cause of the changes in the semiconductor manufacturing equipment 111 may be software of the semiconductor manufacturing equipment 111. When changes occur in software of the semiconductor manufacturing equipment 111, recipe data associated with a manufacturing process of the semiconductor manufacturing equipment 111 may be changed.

The error detector 123_1 may transmit the first equipment setting data EQ_SDATA1 to the data updater 123_2. The error detector 123_1 may receive the first equipment setting data EQ_SDATA1 from the memory 124. The error detector 123_1 may judge that, because of deterioration of semiconductor manufacturing system 110, equipment setting data associated with the mass flow controller MFC is to be updated.

The data updater 123_2 may receive the first equipment setting data EQ_SDATA1 from the error detector 123_1. The data updater 123_2 may update the first equipment setting data EQ_SDATA1 to second equipment setting data EQ_SDATA2. The first equipment setting data EQ_SDATA1 may be, for example, a gas pressure value of the mass flow controller MFC. The second equipment setting data EQ_SDATA2 may be, for example, a new gas pressure value that will be applied to the mass flow controller MFC. The data updater 123_2 may transmit the second equipment setting data EQ_SDATA2 to the semiconductor manufacturing system 110 through the first interface 121.

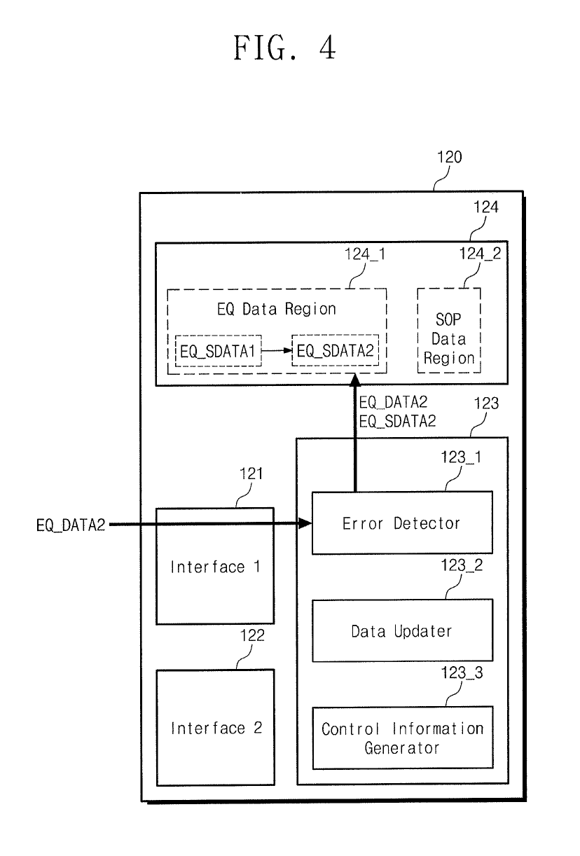

FIG. 4 illustrates an embodiment of a method for storing equipment data of the electronic system 120 in FIG. 2. Referring to FIGS. 3 and 4, the error detector 123_1 of the electronic system 120 may receive second equipment data EQ_DATA2 from the semiconductor manufacturing system 110. The second equipment data EQ_DATA2 may include various types of data associated with a manufacturing process performed, for example, by applying the second equipment setting data EQ_SDATA2 in the semiconductor manufacturing equipment 111.

The error detector 123_1 may analyze the second equipment data EQ_DATA2 to judge whether there changes in the semiconductor manufacturing equipment 111 have occurred. When it is judged that no changes have occurred in the semiconductor manufacturing equipment 111, the error detector 123_1 may store the second equipment data EQ_DATA2 and the second equipment setting data EQ_SDATA2 in the memory 124. The first equipment setting data EQ_SDATA1 stored in the memory 124 may be updated to the second equipment setting data EQ_SDATA2). When it is judged that there are changes in the semiconductor manufacturing equipment 111, the error detector 123_1 may repeat the procedure described with reference to FIG. 3.

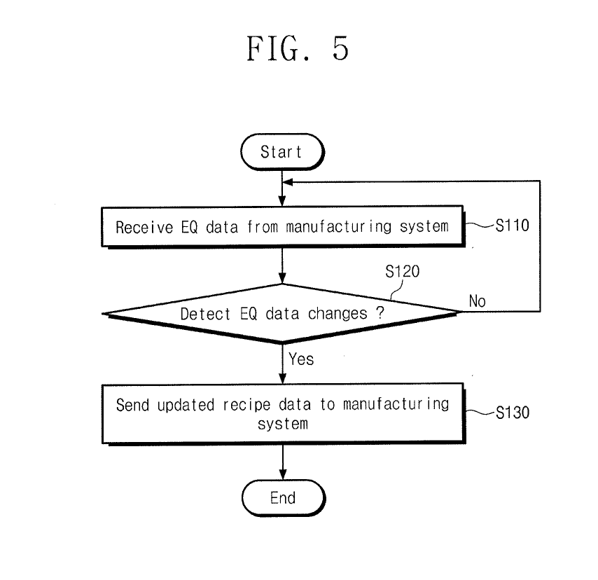

FIG. 5 illustrates an embodiment of a method for updating recipe data of the electronic system 120 in FIG. 2. Referring to FIGS. 2 and 5, in operation S110, the electronic system 120 may receive equipment data from the semiconductor manufacturing system 110.

In operation S120, the electronic system 120 may judge whether changes have occurred in the semiconductor manufacturing equipment 111 based on the equipment data. When changes in the semiconductor manufacturing equipment 111 (Yes) have occurred, the electronic system 120 may analyze the cause of the changes.

In operation S130, in order to solve the cause of the changes, the electronic system 120 updates equipment setting data (e.g., recipe data) and transmits the updated equipment setting data to the semiconductor manufacturing system 110. When no changes have occurred in the semiconductor manufacturing equipment 111 (No), the electronic system 120 may receive equipment data from the semiconductor manufacturing system 110 (S110).

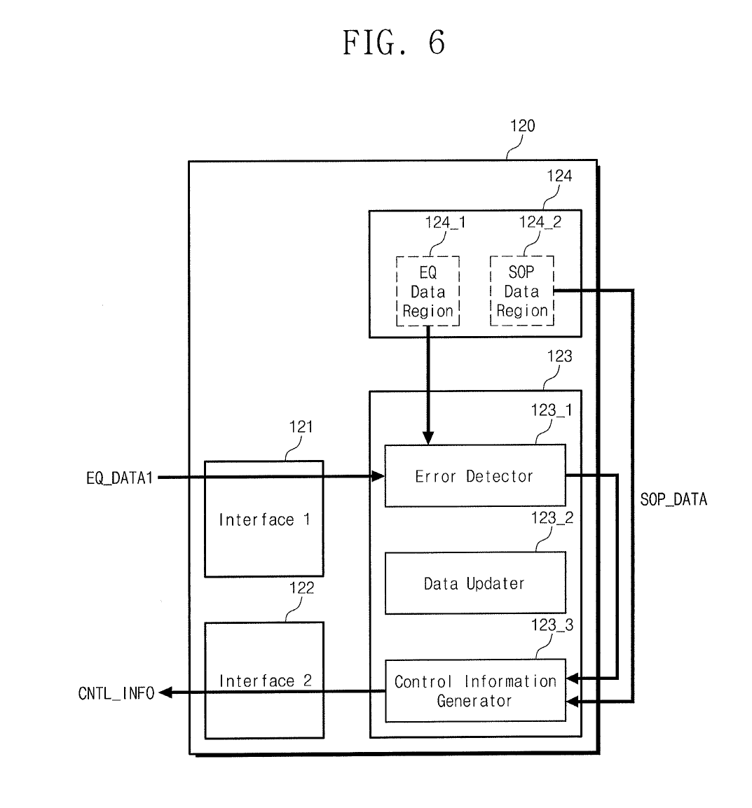

FIG. 6 illustrates an embodiment of a method for generating control information of electronic system 120 in FIG. 2. Referring to FIGS. 2 and 6, the error detector 123_1 of the electronic system 120 may receive the first equipment data EQ_DATA1 through the first interface 121. The error detector 123_1 may analyze the first equipment data EQ_DATA1. The error detector 123_1 may receive the equipment data received before the first equipment data EQ_DATA1 from the memory 124. The error detector 123_1 may judge whether changes have occurred in semiconductor manufacturing equipment 111, for example, by comparing the equipment data received before the first equipment data EQ_DATA1 with the first equipment data EQ_DATA1.

For example, when a temperature value and a pressure value in the first equipment data EQ_DATA1 increase by more than a reference value, as compared with the temperature value and the pressure value of the equipment data received before the first equipment data EQ_DATA1, the error detector 123_1 may judge that there are changes in the semiconductor manufacturing equipment 111. When it is judged that there are changes in the semiconductor manufacturing equipment 111, the error detector 123_1 may analyze a cause of the changes.

For example, changes may occur in the mass flow controller MFC of the semiconductor manufacturing equipment 111. The error detector 123_1 may interpret data or components associated with the changes. When the cause of the changes lies in components of the mass flow controller MFC of the semiconductor manufacturing system 110, the error detector 123_1 may transmit information indicating the changed components to the control information generator 123_3. The error detector 123_1 may judge that components associated with the mass flow controller MFC are to be repaired or replaced, for example, because of deterioration or age of the semiconductor manufacturing system 110.

The control information generator 123_3 may receive the information indicating the changed components from the error detector 123_1. The control information generator 123_3 may receive standard operating procedure data SOP_DATA from the memory 124. The control information generator 123_3 may generate control information CNTL_INFO based on the information about changed component and the standard operating procedure data SOP_DATA. The control information generator 123_3 may generate the control information CNTL_INFO, for example, in the form of augmented reality information. When the control information CNTL_INFO is provided as augmented reality information, an engineer may repair or replace the components.

When changes in a valve of the mass flow controller MFC has occurred, the control information generator 123_3 may determine information corresponding to the valve of the mass flow controller MFC in the standard operating procedure data SOP_DATA. The information corresponding to the valve of the mass flow controller MFC may include, for example, a method of replacing or repairing the valve, a valve replacement period, and/or component information of the valve. The control information generator 123_3 may output, through the second interface 122, control information CNTL_INFO including the information corresponding to the changed component(s) (e.g., a valve) and the standard operating procedure data SOP_DATA (e.g., information about valve) corresponding to the changed component.

According to example embodiments, the electronic system 120 may provide the information indicating the changed component and the standard operating procedure data SOP_DATA corresponding to the changed component at the same time. Because of this, the time taken for an engineer to find a method for solving the cause of the changes in the semiconductor manufacturing equipment 111 may be shortened. Thus, the changes in the semiconductor manufacturing equipment 111 may be rapidly solved and an engineer may accurately repair the semiconductor manufacturing equipment 111.

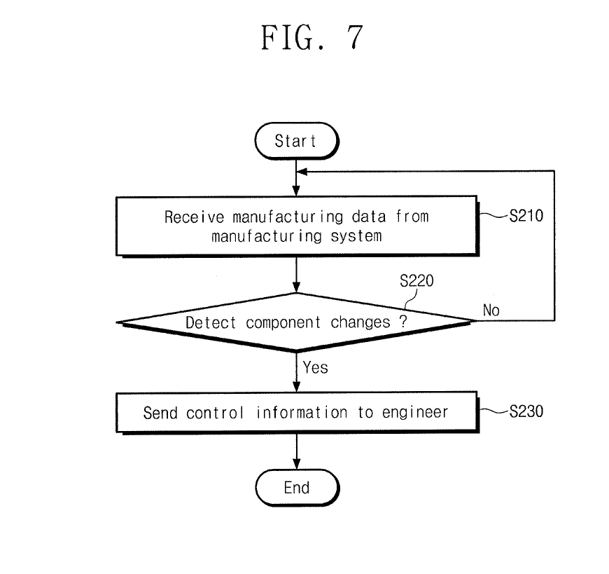

FIG. 7 illustrates an embodiment of a method for generating control information of the electronic system 120 in FIG. 2. Referring to FIGS. 2, 6, and 7, in operation S210, the electronic system 120 may receive equipment data from the semiconductor manufacturing system 110.

In operation S220, the electronic system 120 may judge whether changes have occurred in the semiconductor manufacturing equipment 111 based on the equipment data. When it is judged that the cause of the changes lies in components of the semiconductor manufacturing system 110 (Yes), the electronic system 120 transmits control information to an engineer in operation S230. The control information may include, for example, information indicating or identifying the changed component and standard operating procedure data SOP_DATA of the changed component. When no changes have occurred in the semiconductor manufacturing system 110 (No), the electronic system 120 may receive equipment data from the semiconductor manufacturing system 110 (S210).

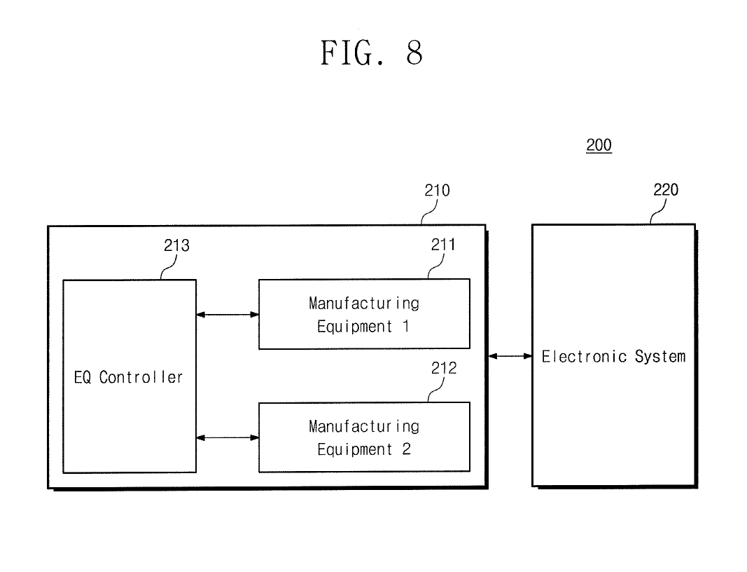

FIG. 8 illustrates another embodiment of a semiconductor manufacturing and management system 200 which may include a semiconductor manufacturing system 210 and an electronic system 220.

The semiconductor manufacturing system 210 may include a first semiconductor manufacturing equipment 211, a second semiconductor manufacturing equipment 212, and a manufacturing equipment controller 213. The first and second semiconductor manufacturing equipment 211 and 212 may be, for example, devices for a manufacturing process of the semiconductor device. Each of the first and second semiconductor manufacturing equipment 211 and 212 may be similar to or the same as the semiconductor manufacturing equipment 111 in FIG. 1. The first and second semiconductor manufacturing equipment 211 and 212 may be, for example, homogeneous equipment. Each of the first and second semiconductor manufacturing equipment 211 and 212 may transmit equipment data generated in a manufacturing process of the semiconductor device to the manufacturing equipment controller 213.

The manufacturing equipment controller 213 may receive equipment data from the first and second semiconductor manufacturing equipment 211 and 212. The manufacturing equipment controller 213 may monitor an operation status of the first and second semiconductor manufacturing equipment 211 and 212. The manufacturing equipment controller 213 may be, for example, similar to or the same as the manufacturing equipment controller 112 in FIG. 1.

The electronic system 220 may receive all equipment data associated with a manufacturing process of the first and second semiconductor manufacturing equipment 211 and 212 from the semiconductor manufacturing system 210. The electronic system 220 may receive equipment data from at least one of the first or second semiconductor manufacturing equipment 211 and 212 or the manufacturing equipment controller 213.

The electronic system 220 may analyze the received equipment data. When it is judged that there are errors in the equipment data, the electronic system 220 may update data including the cause of the errors among equipment setting data stored in the manufacturing equipment controller 213 to new data. When it is judged that there is an error in at least one component of the first or second semiconductor manufacturing equipment 211 and 212, the electronic system 220 may provide information including the cause of the changes, changed components, and/or recommended corresponding methods to an engineer. The electronic system 220 may provide working information reflecting current situation information of the semiconductor manufacturing system 210 to an engineer.

The electronic system 220 may receive equipment data including information indicating changes of at least one of the first or second semiconductor manufacturing equipment 211 and 212 from the semiconductor manufacturing system 210. When information corresponding to changed equipment setting data is in the equipment data, the electronic system 220 may update data indicating the cause of the change among the equipment setting data stored in the manufacturing equipment controller 213 to new data. When information indicating changes in components of at least one of the first or second semiconductor manufacturing equipment 211 and 212 is in the equipment data, the electronic system 220 may provide information indicating the cause of the changes, changed components, and/or recommended corresponding methods to an engineer. The electronic system 220 may receive equipment data including the information indicating the changes.

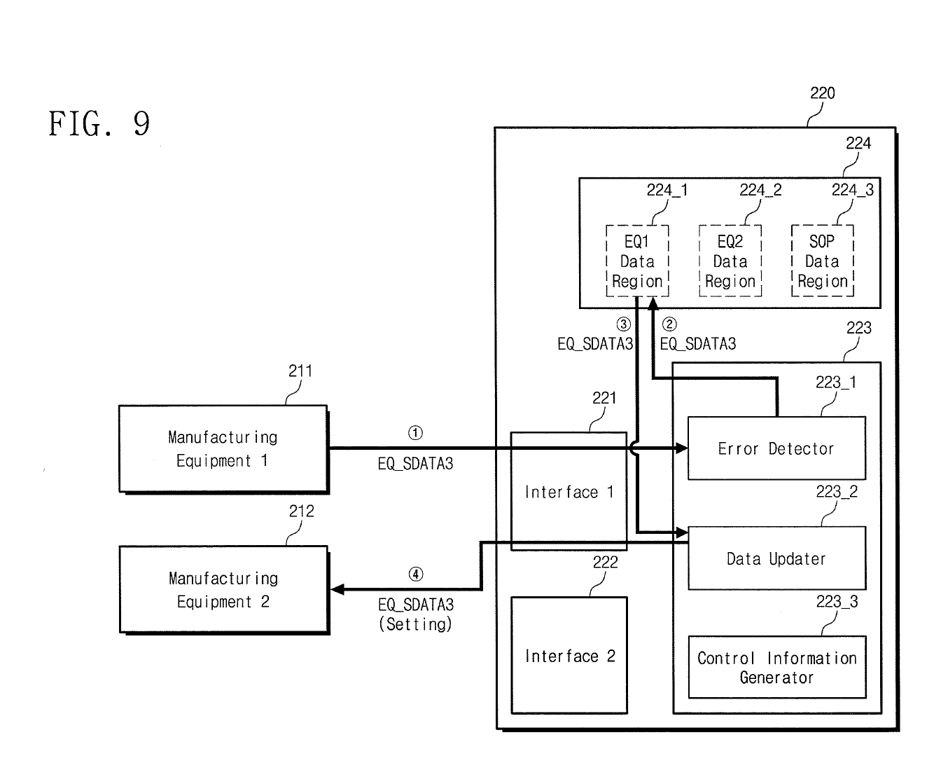

FIG. 9 illustrates an embodiment of a method for setting semiconductor manufacturing equipment of an electronic system 220 in FIG. 8. Referring to FIG. 9, the electronic system 220 may include a first interface 221, a second interface 222, a processor 223, and a memory 224. Each of the first and second interfaces 221 and 222 may be the same as or similar to the first and second interfaces 121 and 122 in FIG. 2.

The electronic system 220 may be implemented, for example, by a desktop computer, a laptop computer, a workstation, a server system, or another processing system. The electronic system 220 may communicate with the first and second semiconductor manufacturing equipment 211 and 212 through the first interface 221. For example, in the first semiconductor manufacturing equipment 211, hardware and software are set to allow a manufacturing process to be performed on the semiconductor device. In the second semiconductor manufacturing equipment 212, hardware and software are not set such that a manufacturing process can be performed on the semiconductor device.

The first interface 221 may receive third equipment setting data EQ_SDATA3 from the first semiconductor manufacturing equipment 211. The third equipment setting data EQ_SDATA3 may include information corresponding to manufacturing process conditions set in the first semiconductor manufacturing equipment 211. The first interface 221 may transmit the received third equipment setting data EQ_SDATA3 to the processor 223 \textcircled{1}.

The processor 223 may include an error detector 223_1, a data updater 223_2, and a control information generator 223_3. The error detector 223_1, the data updater 223_2, and the control information generator 223_3 may be, for example, similar to the error detector 123_1, the data updater 123_2, and the control information generator 123_3 illustrated in FIG. 2, respectively.

The error detector 223_1 may analyze the third equipment setting data EQ_SDATA3 from the first semiconductor manufacturing equipment 211. The error detector 223_1 may analyze the third equipment setting data EQ_SDATA3 to interpret or determine manufacturing process conditions of first semiconductor manufacturing equipment 211. For example, the error detector 223_1 may determine whether the first semiconductor manufacturing equipment 211 is set at an optimum manufacturing process condition through analysis of the third equipment setting data EQ_SDATA3. When it is judged that the first semiconductor manufacturing equipment 211 is set at an optimum manufacturing process condition, the error detector 223_1 may store the third equipment setting data EQ_SDATA3 in the memory 224 \textcircled{3}. The optimum manufacturing process condition may be satisfied when no change has occurred in the semiconductor manufacturing equipment

An engineer may set multiple manufacturing process conditions to set a semiconductor manufacturing equipment (e.g., second semiconductor manufacturing equipment 212) in which hardware or software is not set, such that a manufacturing process may be performed to a state in which a manufacturing process may be performed. Because of this, in the process of setting the manufacturing process conditions, errors may occur and it may take a lot of time to find the cause of the errors.

The data updater 223_2 of the processor 223 may set the second semiconductor manufacturing equipment 212 using data set with the optimum manufacturing process condition. For example, the data updater 223_2 may receive the third equipment setting data EQ_SDATA3 from the memory 224 \textcircled{3}. The data updater 223_2 may transmit the third equipment setting data EQ_SDATA3 to the second semiconductor manufacturing equipment 212 through the first interface 221 \textcircled{4}. A manufacturing process condition of the second semiconductor manufacturing equipment 212 may be set based on the third equipment setting data EQ_SDATA3.

In this manner, the manufacturing process condition of the second semiconductor manufacturing equipment 212 may be rapidly set. Since the manufacturing process condition of the second semiconductor manufacturing equipment 212 is set to data (e.g., third equipment setting data EQ_SDATA3) set with the optimum manufacturing process condition, the probability that errors occur may be reduced.

The memory 224 may include a first manufacturing equipment data area 224_1, a second manufacturing equipment data area 224_2, and a standard operating procedure data SOP_DATA area 224_3. The first manufacturing equipment data area 224_1 may store data (e.g., third equipment setting data EQ_SDATA3) with respect to a manufacturing process condition of the first semiconductor manufacturing equipment 211 and equipment data generated in a manufacturing process of the first semiconductor manufacturing equipment 211. The second manufacturing equipment data area 224_2 may store data with respect to a manufacturing process condition of the second semiconductor manufacturing equipment 212 and equipment data generated in a manufacturing process of the second semiconductor manufacturing equipment 212. The memory 224 may store the third equipment setting data EQ_SDATA3 from the processor 223. The third equipment setting data EQ_SDATA3 may be stored in the first manufacturing equipment data area 224_1 of the memory 224.

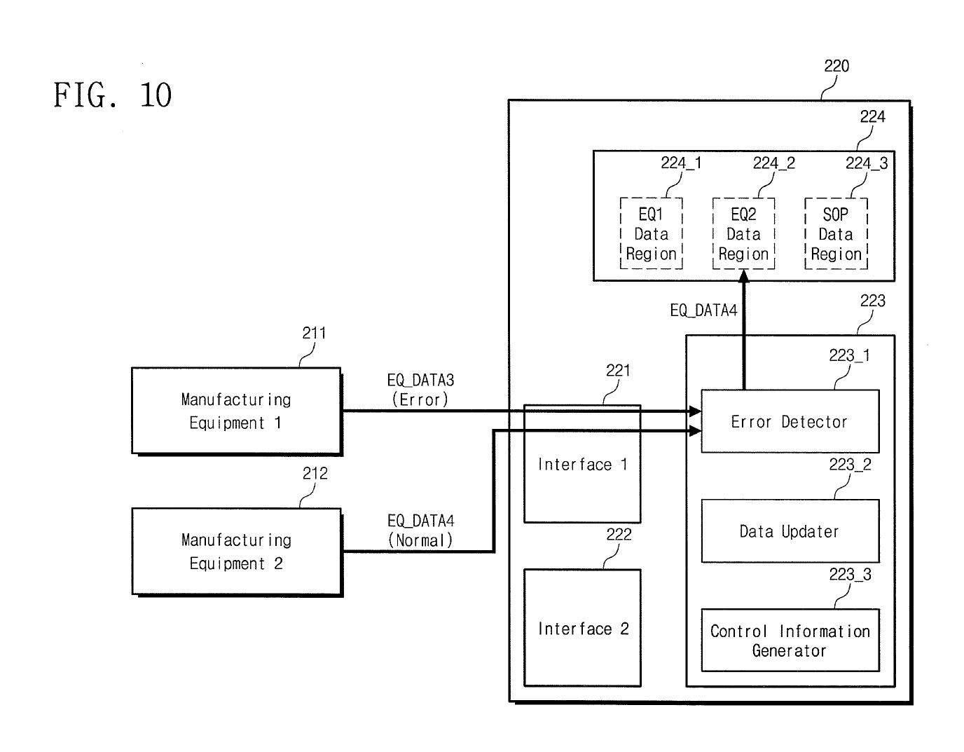

FIG. 10 illustrates an embodiment of a method for storing equipment data of the electronic system 220 in FIG. 8. Referring to FIGS. 8 and 10, the electronic system 220 may communicate with the first and second semiconductor manufacturing equipment 211 and 212 through the first interface 221.

The first interface 221 may receive third equipment data EQ_DATA3 from the first semiconductor manufacturing equipment 211 and may receive fourth equipment data EQ_DATA4 from the second semiconductor manufacturing equipment 212. Each of the third and fourth equipment data EQ_DATA3, EQ_DATA4 may include various data that occurs in a manufacturing process of the first and second semiconductor manufacturing equipment 211 and 212. For example, the third equipment data EQ_DATA3 may be error data including error information, and the fourth equipment data EQ_DATA4 may be normal data not including error information. The first interface 221 may transmit the third and fourth equipment data EQ_DATA3 and EQ_DATA4 to the error detector 223_1 of the processor 223.

The error detector 223_1 may analyze the third and fourth equipment data EQ_DATA3, EQ_DATA4. The error detector 223_1 may judge whether each of the third and fourth equipment data EQ_DATA3, EQ_DATA4 includes error information. When it is judged that the third equipment data EQ_DATA3 includes error information, the error detector 223_1 does not store the third equipment data EQ_DATA3 in the memory 224. When it is judged that the fourth equipment data EQ_DATA4 does not include error information, the error detector 223_1 may store the fourth equipment data EQ_DATA4 in the memory 224.

When the cause of the error information indicated in the third equipment data EQ_DATA3 is data associated with a manufacturing process of the first semiconductor manufacturing equipment 211, the error detector 123_1 updates the data associated with the manufacturing process of the first semiconductor manufacturing equipment 211.

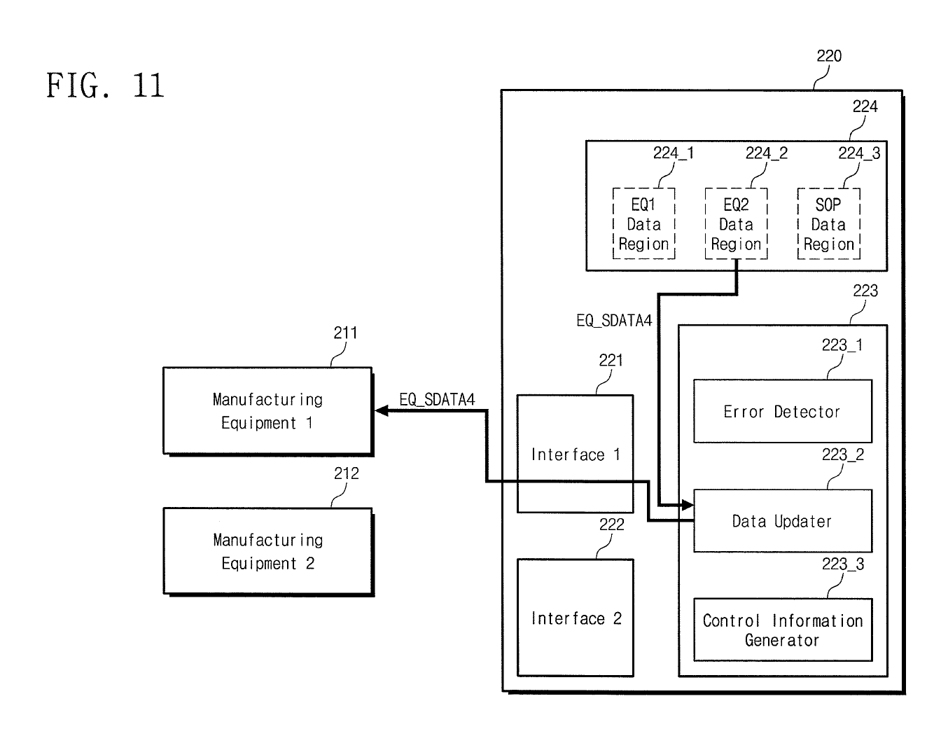

FIG. 11 illustrates an embodiment of a method for updating data of a first semiconductor manufacturing equipment of the electronic system 220 in FIG. 8. Referring to FIGS. 8 to 11, the data updater 223_2 of the processor 223 may receive fourth equipment setting data EQ_SDATA4 from the memory 224. The fourth equipment setting data EQ_SDATA4 is data corresponding to manufacturing process conditions of the second semiconductor manufacturing equipment 212. The fourth equipment setting data EQ_SDATA4 may be received from the semiconductor manufacturing system 210 through the first interface 221. The fourth equipment setting data EQ_SDATA4 may be stored in the memory 224 in advance.

The data updater 223_2 may update third equipment setting data EQ_SDATA3 of the first semiconductor manufacturing equipment 211 to the fourth equipment setting data EQ_SDATA4. The data updater 123_2 may transmit the fourth equipment setting data EQ_SDATA4 to the first semiconductor manufacturing equipment 211 through the first interface 121.

The error detector 223_1 may receive equipment data corresponding to a manufacturing process performed by applying the fourth equipment setting data EQ_SDATA4 from the first semiconductor manufacturing equipment 211. When there is no error in the equipment data received from the first semiconductor manufacturing equipment 211, the error detector 223_1 may store the fourth equipment setting data EQ_SDATA4 in the memory 224.

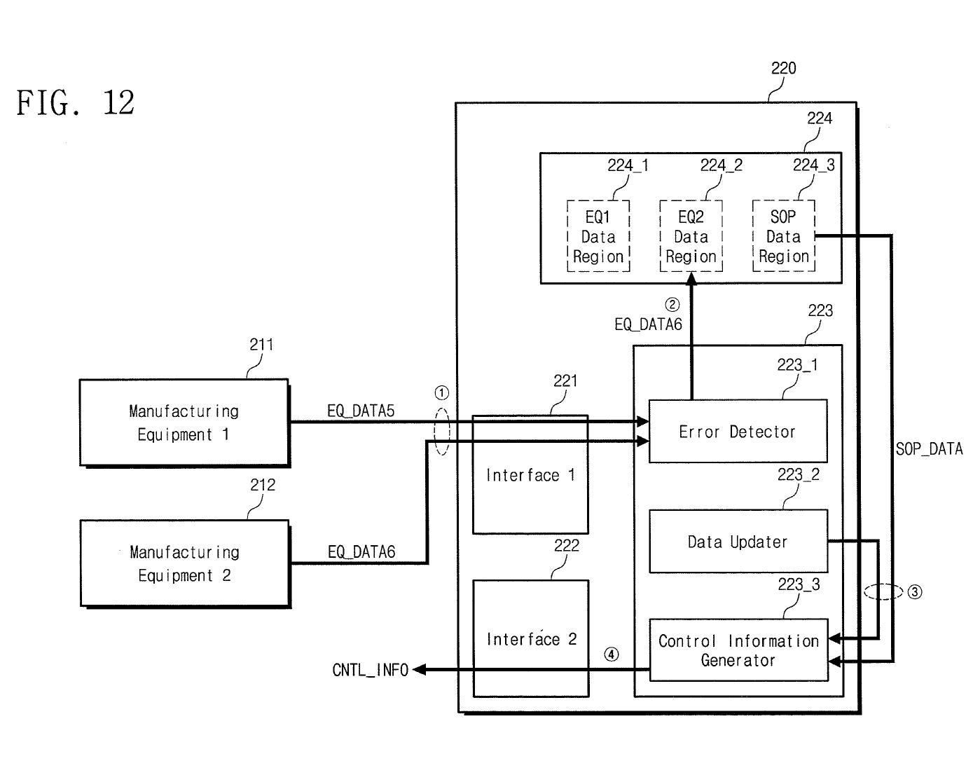

FIG. 12 illustrates another embodiment of a method for updating data of a first semiconductor manufacturing equipment of the electronic system 220 in FIG. 8. Referring to FIGS. 8 and 12, the electronic system 220 may communicate with the first and second semiconductor manufacturing equipment 211 and 212 through the first interface 221.

The first interface 221 may receive may receive fifth equipment data EQ_DATA5 from the first semiconductor manufacturing equipment 211 and may receive sixth equipment data EQ_DATA6 from the second semiconductor manufacturing equipment 212. Each of the fifth and sixth equipment data EQ_DATA5 and EQ_DATA6 may include various data that pertains to a manufacturing process of the first and second semiconductor manufacturing equipment 211 and 212. The fifth equipment data EQ_DATA5 may be error data that includes error information. The sixth equipment data EQ_DATA6 may be normal data that does not include error information. The first interface 221 may transmit the fifth and sixth equipment data EQ_DATA5 and EQ_DATA6 to the error detector 223_1 \textcircled{1}.

The error detector 223_1 may judge whether each of the fifth and sixth equipment data EQ_DATA5, EQ_DATA6 includes error information. When it is judged that the fifth equipment data EQ_DATA5 includes error information, the error detector 223_1 does not store the fifth equipment data EQ_DATA5 in the memory 224. When it is judged that the sixth equipment data EQ_DATA6 does not include error information, the error detector 223_1 may store the sixth equipment data EQ_DATA6 in the memory 224 \textcircled{2}.

When the cause of the error information in the fifth equipment data EQ_DATA5 includes components of the first semiconductor manufacturing equipment 211, the error detector 223_1 may transmit information indicative of the changed component to the control information generator 223_3. For example, the error detector 223_1 may judge that components associated with the mass flow controller MFC is to be repaired or replaced due to deterioration of the first semiconductor manufacturing equipment 211.

The control information generator 223_3 may receive the information indicating the changed component from the error detector 223_1 and may receive standard operating procedure data SOP_DATA from the memory 224 \textcircled{3}. The control information generator 223_3 may generate control information CNTL_INFO based on the information indicating the changed component and the standard operating procedure data SOP_DATA. For example, the control information generator 223_3 may output control information CNTL_INFO including the information indicating the changed component and the standard operating procedure data SOP_DATA corresponding to the changed component through the second interface 122 \textcircled{4}.

In some embodiments, the first semiconductor manufacturing equipment 211 and the second semiconductor manufacturing equipment 212 may be different types. The electronic system 220 may include operation information of each of the first semiconductor manufacturing equipment 211 and the second semiconductor manufacturing equipment 212. A case may occur where equipment setting data of the second semiconductor manufacturing equipment 212 is updated based on equipment setting data of the first semiconductor manufacturing equipment 211. The electronic system 220 may process the equipment setting data of the first semiconductor manufacturing equipment 211 in an appropriate form for the second semiconductor manufacturing equipment 212 with reference to the operation information. The electronic system 220 may provide the processed equipment setting data of the first semiconductor manufacturing equipment 211 to the second semiconductor manufacturing equipment 212.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods described herein.

The controllers, equipment, electronic systems, interfaces, detectors, updaters generators, and other signal generating and signal processing features of the embodiments disclosed herein may be implemented in logic which, for example, may include hardware, software, or both. When implemented at least partially in hardware, the controllers, equipment, electronic systems, interfaces, detectors, updaters generators, and other signal generating and signal processing features may be, for example, any one of a variety of integrated circuits including but not limited to an application-specific integrated circuit, a field-programmable gate array, a combination of logic gates, a system-on-chip, a microprocessor, or another type of processing or control circuit.

When implemented in at least partially in software, the controllers, equipment, electronic systems, interfaces, detectors, updaters generators, and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods described herein.

In accordance with another embodiment, a system includes first logic to detect a change in equipment; second logic to generate control information of the equipment; and third logic to transmit the generated control information to the equipment, wherein the first logic is to detect the change in the equipment based on a first equipment data from the equipment and second equipment data stored in the memory and wherein the equipment includes semiconductor manufacturing equipment. In one embodiment, the first logic though third logic, or a portion thereof, may correspond to the processor of one or more of the foregoing embodiments.

The control information may be generated based on standard operating procedure SOP data stored in the memory. The change in equipment may correspond to an fault occurrence in the semiconductor manufacturing equipment. The fault occurrence may indicate that defects in components, failures of components, or deteriorations of components in the semiconductor manufacturing equipment.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, various changes in form and details may be made without departing from the spirit and scope of the embodiments set forth in the claims.

What is claimed is:

1. An electronic system, comprising:
a memory to store first setting data of a manufacturing process condition of a semiconductor manufacturing equipment; and
a processor to judge whether a change has occurred in the semiconductor manufacturing equipment based on first equipment data from the semiconductor manufacturing equipment and second equipment data stored in the memory before the first equipment data is received, wherein:
the processor is to transmit second setting data to the semiconductor manufacturing equipment when the change has occurred in the semiconductor manufacturing equipment and store the first equipment data in the memory when no change has occurred in the semiconductor manufacturing equipment, the second setting data corresponding to updated first setting data.

2. The electronic system of claim 1, wherein the memory is to store standard operating procedure SOP data corresponding to at least one of an installation method, component information, or a management method of the semiconductor manufacturing equipment.

3. The electronic system of claim 2, wherein when the cause of the changes in the semiconductor manufacturing equipment is components of the semiconductor manufacturing equipment, the processor is to output control information based on the standard operating procedure data.

4. The electronic system of claim 3, further comprising:
a communication interface to output the control information to a device.

5. The electronic system of claim 3, wherein the processor is to output the control information in a form which includes augmented reality information.

6. The electronic system of claim 1, further comprising:
an equipment interface to transmit the second setting data to the semiconductor manufacturing equipment.

7. The electronic system of claim 1, wherein the processor is to:
receive third equipment data generated based on the second setting data from the semiconductor manufacturing equipment,
judge whether the change has occurred in the semiconductor manufacturing equipment based on the second and third equipment data, and
store the third equipment data in the memory when no change has occurred in the semiconductor manufacturing equipment.

8. The electronic system of claim 7, wherein the processor is to:
judge whether the change has occurred in the semiconductor manufacturing equipment based on the second and third equipment data, and
store the second setting data in the memory to replace the first setting data when no change has occurred in the semiconductor manufacturing equipment.

9. The electronic system of claim 1, wherein the first and second setting data includes at least one of temperature information, pressure information, or manufacturing time information set in the semiconductor manufacturing equipment.

10. An electronic system, comprising:
a memory to store first setting data corresponding to a manufacturing process condition of a first semiconductor manufacturing equipment and second setting data corresponding to a manufacturing process condition of a second semiconductor manufacturing equipment; and
a processor to judge a cause of a change in the first semiconductor manufacturing equipment and transmit the second setting data to the first semiconductor manufacturing equipment based on a judgment result when first equipment data from the first semiconductor manufacturing equipment includes first error information corresponding to the first semiconductor manufacturing equipment and second equipment data from the second semiconductor manufacturing equipment does not include second error information corresponding to the second semiconductor manufacturing equipment.

11. The electronic system of claim 10, further comprising:
an equipment interface to transmit the second setting data to the first semiconductor manufacturing equipment.

12. The electronic system of claim 10, wherein the processor is to:
receive third equipment data generated based on the second setting data in the first semiconductor manufacturing equipment, and
store the third equipment data in the memory when the third equipment data does not include the first error information.

13. The electronic system of claim 10, wherein the memory is to:
store standard operating procedure SOP data corresponding to at least one of an installation method, component information, or a management method of the first and second semiconductor manufacturing equipment.

14. The electronic system of claim 13, wherein when the cause of the changes in the semiconductor manufacturing equipment is components of the semiconductor manufacturing equipment, the processor is to output control information based on the standard operating procedure data.

15. The electronic system of claim 14, further comprising:
a communication interface to output the control information to a device.

16. A system, comprising:
first logic to detect a change in equipment;
second logic to generate control information of the equipment; and
third logic to transmit the generated control information to the equipment,
wherein the first logic is to detect the change in the equipment based on a first equipment data from the equipment and second equipment data stored in the memory and wherein the equipment includes semiconductor manufacturing equipment.

17. The system as claimed in claim 16, wherein the control information is generated based on standard operating procedure SOP data stored in the memory.

18. The system as claimed in claim 16, wherein the change in equipment corresponds to a fault occurrence in the semiconductor manufacturing equipment.

19. The system as claimed in claim 18, wherein the fault occurrence indicates that defects in components, failures of components, or deteriorations of components in the semiconductor manufacturing equipment.

20. The system as claimed in claim 16, wherein the control information include an information indicating a changed component in the equipment and a standard operating procedure SOP data of the changed component.
